(19) United States
(12) Patent Application Publication
(10) Pub. No.: US 2013/0087802 A1
(43) Pub. Date: Apr. 11, 2013

(54) THIN FILM TRANSISTOR, FABRICATION METHOD THEREFOR, AND DISPLAY DEVICE

(71) Applicants: Akihiko Kohno, Osaka-shi (JP); Toshio Mizuki, Osaka-shi (JP); Kohichi Tanaka, Osaka-shi (JP)

(72) Inventors: Akihiko Kohno, Osaka-shi (JP); Toshio Mizuki, Osaka-shi (JP); Kohichi Tanaka, Osaka-shi (JP)

(21) Appl. No.: 13/805,412

(22) PCT Filed: Mar. 25, 2011
(86) PCT No.: PCT/JP2011/057333

§ 371 Date: Dec. 19, 2012

(30) Foreign Application Priority Data
Jul. 7, 2010 (JP) 2010-154690

(51) Int. Cl. H01L 29/786; H01L 29/66

(52) U.S. Cl. CPC H01L 29/786; H01L 29/66772
USPC 257/72; 257/66; 438/158

(57) ABSTRACT

It is an object to increase the mobility of a thin film transistor having an active layer including a microcrystalline semiconductor film. Upon fabricating an inverted staggered type TFT 10, a substrate is vacuum-transferred to a plasma enhanced CVD apparatus such that a surface of a microcrystalline silicon film (active layer 40) exposed by gap etching is not exposed to the air. An insulating film 80 is deposited by the plasma enhanced CVD apparatus so as to completely cover the exposed surface of the microcrystalline silicon film. By this, even if the microcrystalline silicon film is exposed to the air, oxygen cannot be adsorbed on the surface thereof and thus diffusion of oxygen into the microcrystalline silicon film can be suppressed. In addition, since N+ silicon films composing contact layers 50a and 50b directly contact with the microcrystalline silicon film, the contact resistance can be reduced. In this manner, the mobility of the TFT 10 having the active layer 40 including the microcrystalline silicon film can be increased.

### TECHNICAL FIELD

The present invention relates to a thin film transistor, a fabrication method therefor, and a display device, and more specifically to a thin film transistor suitably used in an active matrix-type display device, a fabrication method therefor, and a display device.

### BACKGROUND ART

In active matrix-type display devices such as liquid crystal display devices and organic EL (Electro Luminescence) display devices, thin film transistors (hereinafter, referred to as “TFTs”) are widely used as switching elements in pixel portions and transistors that compose drive circuits for driving the pixel portions.

As a thin-film-like silicon film composing an active layer of such a TFT, an amorphous silicon film or polycrystalline silicon film is used. The amorphous silicon film is relatively easy to deposit and is excellent in mass productivity. However, a TFT having an active layer made of an amorphous silicon film (hereinafter, referred to as an “amorphous silicon TFT”) has a problem of a low mobility of carriers in the active layer, compared to a TFT having an active layer made of a polycrystalline silicon film (hereinafter, referred to as a “polycrystalline silicon TFT”).

On the other hand, the polycrystalline silicon TFT has a high mobility of carriers in the active layer and thus can charge a pixel capacitance of a liquid crystal display device, etc., in a short switching time. In addition, since peripheral circuits such as drivers can be formed using polycrystalline silicon TFTs, the peripheral circuits such as drivers can also be formed on a TFT substrate where pixel portions are formed. Therefore, polycrystalline silicon TFTs have started to be used in display devices such as liquid crystal televisions for which there are demands for an increase in definition and high speed drive, as well as an increase in the size of liquid crystal panels. However, there are constraints such as: since the deposition temperature of a polycrystalline silicon film is high, a low-cost glass substrate cannot be used as a substrate on which a polycrystalline silicon film is deposited; and a film thickness needs to be thick in order to increase the grain size of grains.

In view of this, to deal with the demands for an increase in size and definition and high speed drive of display devices, a TFT using a microcrystalline silicon film as an active layer (hereinafter, referred to as a “microcrystalline silicon TFT”) has started to gain attention. However, when a microcrystalline silicon film is deposited using a high density plasma enhanced CVD (Chemical Vapor Deposition) apparatus and then is taken out into the air, oxygen in the air is taken into the microcrystalline silicon film, increasing the oxygen concentration in the microcrystalline silicon film. Due to this, the microcrystalline silicon TFT has a problem of a decrease in the mobility of carriers.

Japanese Patent Application Laid-Open No. 2009-71290 discloses a configuration of an inverted staggered type microcrystalline silicon TFT with a reduced oxygen concentration in a microcrystalline silicon film. According to Japanese Patent Application Laid-Open No. 2009-71290, an active layer is formed to have a two-layer structure including a microcrystalline silicon film and an amorphous silicon film stacked on a top surface of the microcrystalline silicon film. In this case, when a microcrystalline silicon film and an amorphous silicon film are consecutively deposited using a high density plasma enhanced CVD apparatus and taken out into the air, oxygen is adsorbed on a surface of the amorphous silicon film. However, since the amorphous silicon film does not allow oxygen to pass therethrough, the adsorbed oxygen is not taken into the microcrystalline silicon film and thus the oxygen concentration in the microcrystalline silicon film does not increase.

### PRIOR ART DOCUMENT

### Patent Document

[Patent Document 1] Japanese Patent Application Laid-Open No. 2009-71290

### SUMMARY OF THE INVENTION

### Problems to be Solved by the Invention

However, in the TFT described in Japanese Patent Application Laid-Open No. 2009-71290, the amorphous silicon film is sandwiched between the microcrystalline silicon film and an N+ silicon film containing a high concentration of N-type impurities. An on-current (drain current) in such a TFT flows from a drain electrode to a source electrode through the N+ silicon film, the amorphous silicon film, the microcrystalline silicon film, the amorphous silicon film, and the N+ silicon film in this order. Since this current path includes the amorphous silicon film with a low mobility (high resistance value), the microcrystalline silicon film with a high mobility (low resistance value) is not in direct contact with the N+silicon film. Hence, a TFT of such a structure has a problem of being unable to increase the mobility.

An object of the present invention is therefore to provide a thin film transistor that has an active layer including a microcrystalline semiconductor film and has a high mobility, and a fabrication method therefor. In addition, another object of the present invention is to provide a display device using such a thin film transistor.

### Means for Solving the Problems

A first aspect is directed to a thin film transistor formed on an insulating substrate, the thin film transistor comprising:
a gate electrode formed on the insulating substrate;
a gate insulating film that covers the gate electrode;
an active layer formed on a top surface of the gate insulating film so as to extend over the gate electrode as viewed from a top;
two contact layers formed on top surfaces of portions of the active layer at both edges, respectively; and
a source electrode and a drain electrode formed on top surfaces of the two contact layers, respectively, wherein
the active layer includes at least a microcrystalline semiconductor film on a back-channel side, and
a portion of a surface of the microcrystalline semiconductor film sandwiched between the two contact layers is covered with a first insulating film.

A second aspect is such that in the first aspect,
the thin film transistor further comprises second insulating films formed on surfaces of the source electrode and the drain electrode, and
a film thickness of the first insulating film is thicker than a film thickness of the second insulating films.

A third aspect is such that in the first aspect,
the active layer further includes a polycrystalline semiconductor film, and
the microcrystalline semiconductor film is formed on a top surface of the polycrystalline semiconductor film.

A fourth aspect is such that in any of the first to third aspects,
the two contact layers each are made of an impurity semiconductor film containing a high concentration of impurities.

A fifth aspect is directed to a method of fabricating a thin film transistor formed on an insulating substrate, the method comprising the steps of:
forming a gate electrode on the insulating substrate;
forming a gate insulating film so as to cover the gate electrode;
forming a microcrystalline semiconductor film on a top surface of the gate insulating film;
forming an impurity semiconductor film containing a high concentration of impurities on a top surface of the microcrystalline semiconductor film;
forming a metal film on a top surface of the impurity semiconductor film;
forming a resist pattern on a top surface of the metal film;
forming a source electrode and a drain electrode by patterning the metal film using the resist pattern as a mask;
forming two contact layers and an active layer by patterning the impurity semiconductor layer and the microcrystalline semiconductor film using the resist pattern as a mask, the two contact layers being separated from each other on the top surface of the microcrystalline semiconductor film; and
without causing a portion of a surface of the active layer sandwiched between the two contact layers to be exposed to oxygen, covering the portion of the surface of the active layer by a first insulating film.

A sixth aspect is such that in the fifth aspect,
the step of covering the portion of the surface of the active layer by a first insulating film includes the steps of:
   forming the first insulating film so as to cover at least a surface of the resist pattern and the portion of the surface of the active layer;
   causing a part of the resist pattern to be exposed by removing at least a part of the first insulating film; and
   allowing the first insulating film to remain on the portion of the surface of the active layer by lifting off the first insulating film on the resist pattern by removing the resist pattern by immersing the resist pattern in a first resist development solution.

A seventh aspect is such that in the sixth aspect,
the step of covering the portion of the surface of the active layer by a first insulating film further includes the step of wet etching the first insulating film remaining on the portion of the surface of the active layer.

An eighth aspect is such that in the sixth or seventh aspect,
an etching apparatus used in the step of forming two contact layers is connected to a deposition apparatus used in the step of forming the first insulating film, by a vacuum path whose degree of vacuum is maintained at a predetermined value or less, and
the insulating substrate having the two contact layers formed thereon is transferred from the etching apparatus to the deposition apparatus through the vacuum path.

A ninth aspect is such that in the sixth aspect,
the step of causing a part of the resist pattern to be exposed includes the steps of:
   applying a photoresist onto the insulating substrate;
   forming a resist film that completely covers the first insulating film, by curing the photoresist; and
   causing at least a part of the first insulating film to be exposed by dissolving the resist film from a surface thereof, using a second resist development solution.

A tenth aspect is such that in the ninth aspect,
the step of forming a resist film further includes the step of flattening the surface of the resist film.

An eleventh aspect is such that in the fifth aspect,
the method further comprises the step of forming a second insulating film so as to cover the entire insulating substrate including the source electrode and the drain electrode.

A twelfth aspect is directed to a display device comprising: a thin film transistor according to any one of the first to fourth aspects; and an image display portion, wherein
the thin film transistor is used as a switching element in the image display portion.

A thirteenth aspect is such that in the twelfth aspect,
the display device further comprises a peripheral circuit that drives the image display portion, and
the peripheral circuit includes a thin film transistor according to any one of the first to fourth inventions.

### Effects of the Invention

According to the first aspect, since an active layer includes at least a microcrystalline semiconductor film formed on the back-channel side and contact layers are in direct contact with the microcrystalline semiconductor film of the active layer, the contact resistance between the contact layers and the active layer decreases. In addition, a portion of a surface of the microcrystalline semiconductor film sandwiched between the two contact layers is covered with a first insulating film. This prevents the surface of the microcrystalline semiconductor film from being exposed to the air, and thus, oxygen in the air is less likely to diffuse in the microcrystalline semiconductor film. Therefore, the mobility of the thin film transistor having the active layer including the microcrystalline semiconductor film can be increased.

According to the second aspect, the film thickness of the first insulating film formed on the portion of the surface of the microcrystalline semiconductor film is thicker than that of second insulating films formed on surfaces of a source electrode and a drain electrode. By this, impurities are less likely to enter the surface of the microcrystalline semiconductor film formed on the back-channel side of the active layer from the outside and crystal defects resulting from the entered impurities are less likely to be formed. Thus, the off-current of the thin film transistor can be reduced.

According to the third aspect, since the active layer includes a polycrystalline semiconductor film on the gate electrode side, the on-current of the thin film transistor can be increased.

According to the fourth aspect, since the contact layers are made of impurity semiconductor films containing a high concentration of impurities, the contact resistance between the contact layers and the active layer decreases. By this, the mobility of the thin film transistor can be increased.

According to the fifth aspect, by covering a surface of an active layer by a first insulating film, the surface of the active layer that is exposed when forming contact layers by etching an impurity semiconductor film is prevented from being exposed to oxygen. By this, oxygen is less likely to be adsorbed on the surface of the active layer, enabling to suppress diffusion of oxygen in the active layer. In addition, since the impurity semiconductor films composing the contact layers are in direct contact with a microcrystalline semiconductor film composing the active layer, the contact resistance between the contact layers and the active layer decreases. Therefore, a thin film transistor with a high mobility can be fabricated. Furthermore, there is no need to form an etching stopper layer in advance on the surface of the active layer, as a protective film for the formation of the contact layers. By this, a thin film transistor can be fabricated using photomasks of the same number as that of the conventional fabrication method.

According to the sixth aspect, the first insulating film is formed so as to cover a surface of a resist pattern which is used for patterning of a source electrode, a drain electrode, etc., and to cover the surface of the active layer. After causing a part of the resist pattern to be exposed by removing a part of the first insulating film, the resist pattern is immersed in a first resist development solution. By this, the resist pattern is dissolved in the first resist development solution and removed, and thus, the first insulating film covering the surface thereof is also removed by lift-off. By thus removing the first insulating film on the resist pattern, the first insulating film can remain on the surface of the active layer, enabling to simplify a method of fabricating a thin film transistor.

According to the seventh aspect, by wet etching the first insulating film remaining on the surface of the active layer, a portion of the first insulating film that has not been able to be removed by the lift-off is removed and the shape of the first insulating film can be adjusted.

According to the eighth aspect, an etching apparatus for etching an impurity semiconductor film to form contact layers is connected to a deposition apparatus for forming a first insulating film on a surface of an active layer, by a vacuum path. Since an insulating substrate having two contact layers formed thereon is transferred from the etching apparatus to the deposition apparatus through the vacuum path, a first insulating film can be formed without causing an exposed surface of an active layer to be exposed to oxygen. By this, diffusion of oxygen in the active layer can be suppressed and thus the mobility of a thin film transistor can be increased.

According to the ninth aspect, a resist film that completely covers the first insulating film is formed by applying a photoresist onto the insulating substrate and curing the photoresist. Then, the resist film is dissolved in a second resist development solution from a surface thereof. By this, at least apart of the first insulating film can be easily exposed, enabling to simplify a method of fabricating a thin film transistor.

According to the tenth aspect, by flattening the surface of the resist film, projections and depressions on the surface of the resist film which occur upon curing of the photoresist are polished to flatten the resist film, and the film thickness of the resist film can be adjusted.

According to the eleventh aspect, a second insulating film is deposited on the first insulating film on the surface of the active layer. Hence, the film thickness of the insulating film on the surface of the active layer is thicker than that of the insulating films on the source electrode and the drain electrode. By this, impurities are less likely to enter the surface of the microcrystalline semiconductor film from the outside and crystal defects resulting from the entered impurities are less likely to be formed on a surface of the microcrystalline semiconductor film on the back-channel side. Thus, the off-current of the thin film transistor can be reduced.

According to the twelfth aspect, since the thin film transistor is used as a switching element in a pixel portion of a display device, by reducing the size of the thin film transistor, the aperture ratio can be increased. In addition, since the mobility of the thin film transistor is high, switching operation can be performed at high speed. By this, the thin film transistor can charge a image signal provided from a source wiring line in a pixel capacitance in a short time, and thus, high definition can be achieved by increasing the number of pixel portions included in an image display portion.

According to the thirteenth aspect, since a peripheral circuit is formed using the thin film transistor, the operating speed of the peripheral circuit can be increased. By this, the circuit size of the peripheral circuit is reduced, and thus, the size of a picture-frame portion of a display panel where the image display portion is formed is reduced, enabling to miniaturize the display device. In addition, the performance and image quality of the display device can be increased.

### BRIEF DESCRIPTION OF THE DRAWINGS

FIG. 1 is a cross-sectional view showing a cross section after formation of contact layers of an inverted staggered type microcrystalline silicon TFT which is a first comparative example.

FIG. 2 is a step flowchart showing a method of fabricating the TFT shown in FIG. 1.

FIG. 3 is a cross-sectional view showing a cross section after formation of contact layers of an inverted staggered type microcrystalline silicon TFT which is a second comparative example.

FIG. 4 is a step flowchart showing a method of fabricating the TFT shown in FIG. 3.

FIG. 5 is a cross-sectional view showing a configuration of an inverted staggered type microcrystalline silicon TFT according to the present embodiment.

FIG. 6 is a step flowchart showing a method of fabricating the microcrystalline silicon TFT shown in FIG. 5.

FIG. 7 is a step flowchart showing the method of fabricating the microcrystalline silicon TFT shown in FIG. 5.

FIGS. 8(A) to (D) are step cross-sectional views showing each fabrication step of the microcrystalline silicon TFT shown in FIG. 5.

FIGS. 9(A) to (C) are step cross-sectional views showing each fabrication step of the microcrystalline silicon TFT shown in FIG. 5.

FIGS. 10(A) to (C) are step cross-sectional views showing each fabrication step of the microcrystalline silicon TFT shown in FIG. 5.

FIGS. 11(A) to (C) are step cross-sectional views showing each fabrication step of the microcrystalline silicon TFT shown in FIG. 5.

FIG. 12 is a block diagram showing a configuration of a dry etching apparatus and a plasma enhanced CVD apparatus for use in the fabrication steps of the microcrystalline silicon TFT shown in FIG. 5.

FIG. 13 is a diagram showing the crystallinity observation results of active layers and measurement results of mobility of the TFTs of the present embodiment, the first comparative example, and the second comparative example.

FIG. 14 is a diagram showing the measurement results of the gate voltage-drain current characteristics of the TFTs of the present embodiment, the first comparative example, and the second comparative example.

FIG. 15 is a cross-sectional view corresponding to FIG. 9(C) of an inverted staggered type microcrystalline silicon TFT according to a variant of the present embodiment.

FIG. 16(A) is a perspective view showing a liquid crystal panel of an active matrix-type liquid crystal display device, and FIG. 16(B) is a perspective view showing a TFT substrate included in the liquid crystal panel shown in FIG. 16(A).

### MODES FOR CARRYING OUT THE INVENTION

### 1. Basic Consideration

A microcrystalline silicon film has the following problems caused by its crystal structures. Since a microcrystalline silicon film has columnar crystal structures, oxygen is likely to diffuse in the microcrystalline silicon film along grain boundaries. Due to this, when a microcrystalline silicon film is deposited using a high density plasma enhanced apparatus and the deposited microcrystalline silicon film is taken out of the high density plasma enhanced apparatus into the air, oxygen in the air is adsorbed on a surface of the microcrystalline silicon film and diffuses in the microcrystalline silicon film along grain boundaries. When the oxygen concentration in the microcrystalline silicon film thus increases, crystal defects are generated in the microcrystalline silicon film. The generated crystal defects trap electrons and holes. Hence, an inverted staggered type microcrystalline silicon TFT having a microcrystalline silicon film as an active layer has a problem of a decrease in mobility. Furthermore, there may be a case in which a silicon film with a low mobility may be included in a path from a drain electrode to a source electrode, through which an on-current flows. In such a case, there is a problem of a decrease in the mobility of the TFT.

From these facts, in order to increase the mobility of an inverted staggered type microcrystalline silicon TFT, a microcrystalline silicon TFT needs to satisfy both of the following two conditions. The first condition is to reduce the oxygen concentration in a microcrystalline silicon film composing an active layer. The second condition is to bring N+ silicon layers composing contact layers into direct contact with the microcrystalline silicon film composing the active layer. Hence, the configurations of two types of inverted staggered type microcrystalline silicon TFTs which are conventionally known will be described as first and second comparative examples, to clarify problems with the configurations and fabrication methods therefor.

Note that the configurations of and fabrication methods for microcrystalline silicon TFTs which will be described as the first and second comparative examples have lots of common parts with the configuration of and fabrication method for a microcrystalline silicon TFT according to the present embodiment which will be described later. Hence, to avoid overlapping description as much as possible, description of the first and second comparative examples is kept to a minimum necessary to clarify the problems with the configurations and fabrication methods, and details will be described in the present embodiment.

### 1.1 First Comparative Example

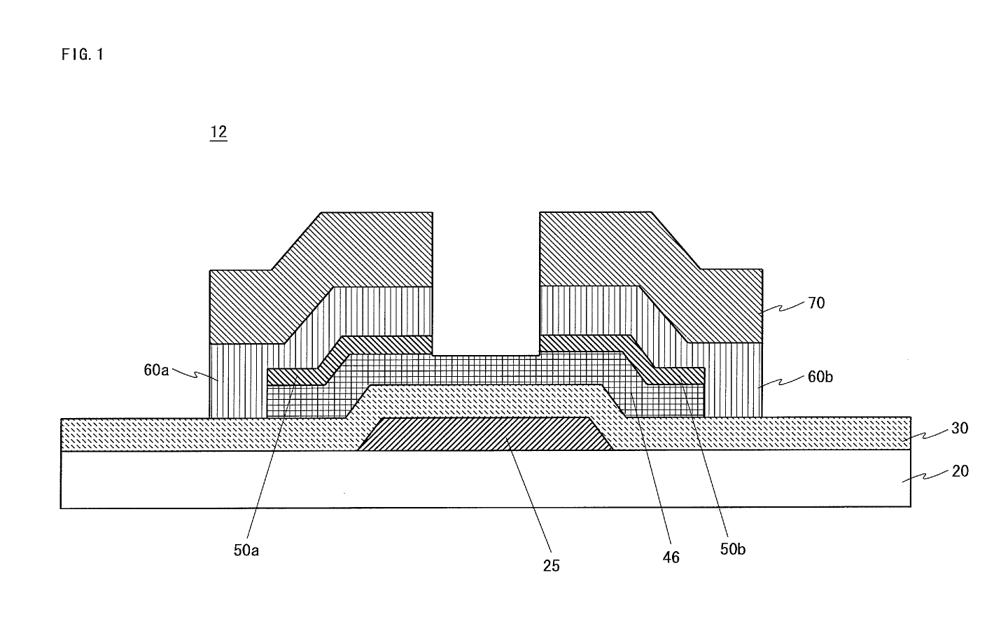

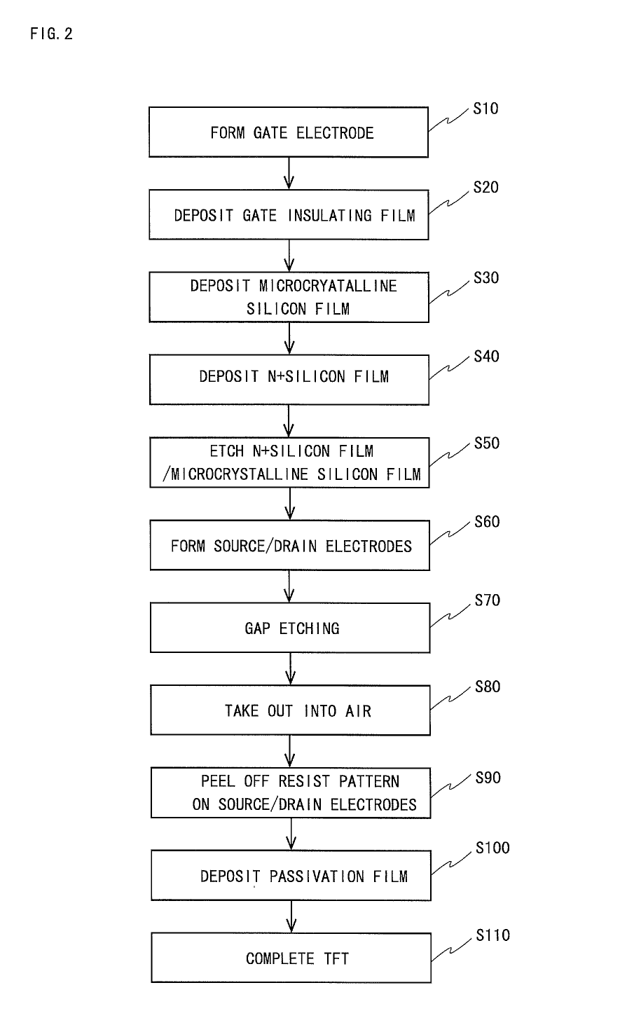

FIG. 1 is a cross-sectional view showing a cross section after formation of contact layers 50a and 50b of an inverted staggered type microcrystalline silicon TFT 12 which is a first comparative example. FIG. 2 is a step flowchart showing a method of fabricating the TFT 12 shown in FIG. 1. The TFT 12 is a TFT having the same configuration as the TFT briefly described in the background art. Note that an after-treatment process to prevent after-corrosion caused by residual chlorine (Cl2) gas, and hydrogen plasma treatment to terminate the dangling bonds of silicon atoms on a surface of a microcrystalline silicon film are also performed. However, description thereof is omitted in the first comparative example.

With reference to FIGS. 1 and 2, the configuration of and fabrication method for the TFT 12 will be described. A titanium (Ti) film of a film thickness of 100 nm, for example, is deposited on a glass substrate 20 which is an insulating substrate, and the titanium film is patterned, thereby forming a gate electrode 25 (step S10). A gate insulating film 30 is formed so as to cover the entire surface of the glass substrate 20 including the gate electrode 25 (step S20). The gate insulating film 30 is made of a silicon nitride (SiNx) film of a film thickness of 410 nm, for example.

A microcrystalline silicon film of a film thickness of 50 nm, for example, is deposited on a surface of the gate insulating film 30, using a high density plasma enhanced CVD apparatus (step S30). The microcrystalline silicon film is deposited using monosilane (SiH4) gas and argon (Ar) gas as raw material gas, and the grain size thereof is 2 to 100 nm. Then, using the same high density plasma enhanced CVD apparatus, an N+ silicon film of a film thickness of 50 nm, for example, is deposited on a surface of the microcrystalline silicon film by changing the deposition conditions (step S40). The N+ silicon film is an amorphous silicon film containing a high concentration of N-type impurities such as phosphorus (P). Then, the glass substrate 20 having the N+ silicon film formed thereon is taken out of the high density plasma enhanced CVD apparatus into the air. At this time, the microcrystalline silicon film is covered with the N+ silicon film. Oxygen that is adsorbed on a surface of the N+ silicon film when taken out into the air cannot pass through the N+ silicon film and thus does not diffuse in the microcrystalline silicon film.

Using, as a mask, a resist pattern formed on the surface of the N+ silicon film, the N+ silicon film and the microcrystalline silicon film are consecutively etched in this order by a dry etching method (step S50). By this, an island-like active layer 46 extending laterally over the gate electrode 25 as viewed from the top is formed, and the N+ silicon film of the same shape as the active layer 46 is formed on a top surface of the active layer 46.

A titanium film of a film thickness of 100 nm, for example, is deposited so as to cover the entire surface of the glass substrate 20 including the N+ silicon film. Using, as a mask, a resist pattern 70 formed on a surface of the titanium film, the titanium film is etched using a dry etching apparatus, thereby forming a source electrode 60a and a drain electrode 60b (step S60).

Furthermore, using the same dry etching apparatus and using the resist pattern 70 as a mask, the N+ silicon film is etched (hereinafter, referred to as “gap etching”) (step S70). As shown in FIG. 1, by the gap etching, the N+ silicon film is separated from each other to the left and right, whereby two contact layers 50a and 50b are formed and a surface of the microcrystalline silicon film composing the active layer 46 is exposed. The glass substrate 20 having been subjected to the gap etching is taken out of the dry etching apparatus into the air (step S80). At this time, oxygen in the air is adsorbed on the exposed surface of the microcrystalline silicon film, and the adsorbed oxygen diffuses in the microcrystalline silicon film along grain boundaries.

The resist pattern 70 formed on the source electrode 60a and the drain electrode 60b is peeled off (step S90). Then, a passivation film is deposited so as to cover the entire surface of the glass substrate 20 including the source electrode 60a and the drain electrode 60b, thereby sealing a TFT 12 (step S100). The passivation film is a silicon nitride film of a film thickness of 265 nm, for example. Furthermore, a heating process is performed in a nitrogen atmosphere for one hour, whereby the TFT 12 is completed (step S110).

### 1.1.1 Problems in the First Comparative Example

According to the first comparative example, the active layer 46 of the TFT 12 is made of a microcrystalline silicon film and the contact layers 50a and 50b are made of N+ silicon films. Since the contact layers 50a and 50b are formed on the top surface of the active layer 46, the N+ silicon films are in direct contact with the microcrystalline silicon film. Therefore, the TFT 12 satisfies the second condition.

However, when the glass substrate 20 where the surface of the microcrystalline silicon film is exposed by gap etching is taken out of the dry etching apparatus into the air, the surface of the microcrystalline silicon film is exposed. Oxygen in the air is adsorbed on the surface of the microcrystalline silicon film and further diffuses in the microcrystalline silicon film along grain boundaries. Due to this, the oxygen concentration in the microcrystalline silicon film increases and accordingly the first condition is not satisfied. As such, the TFT 12 of the first comparative example does not satisfy the first condition. Therefore, the mobility of the TFT 12 decreases.

### 1.2 Second Comparative Example

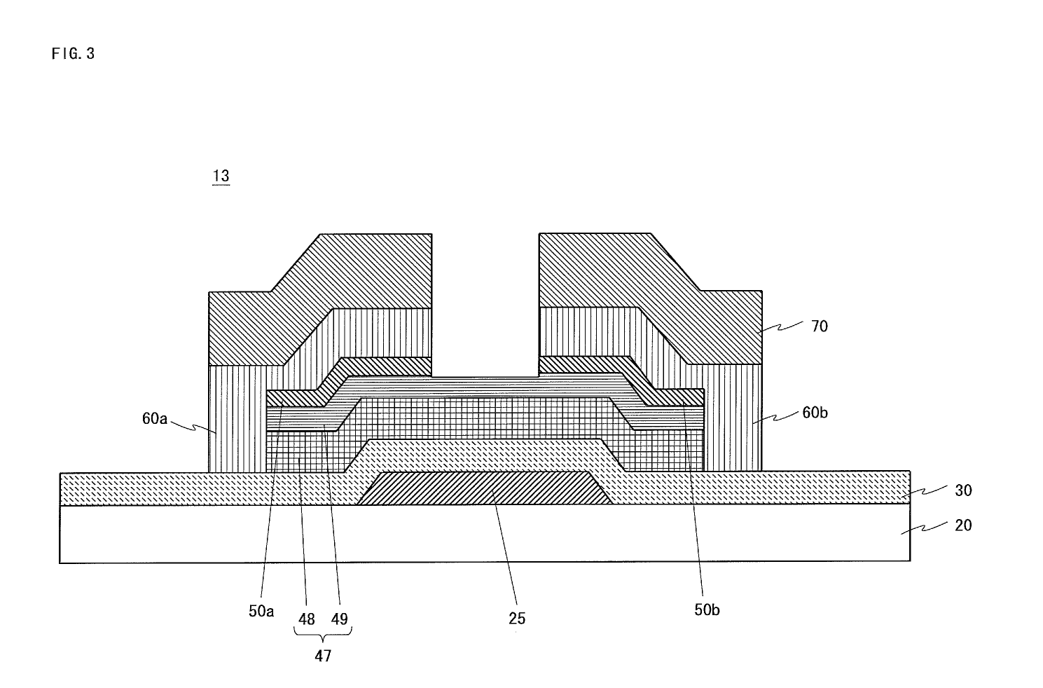

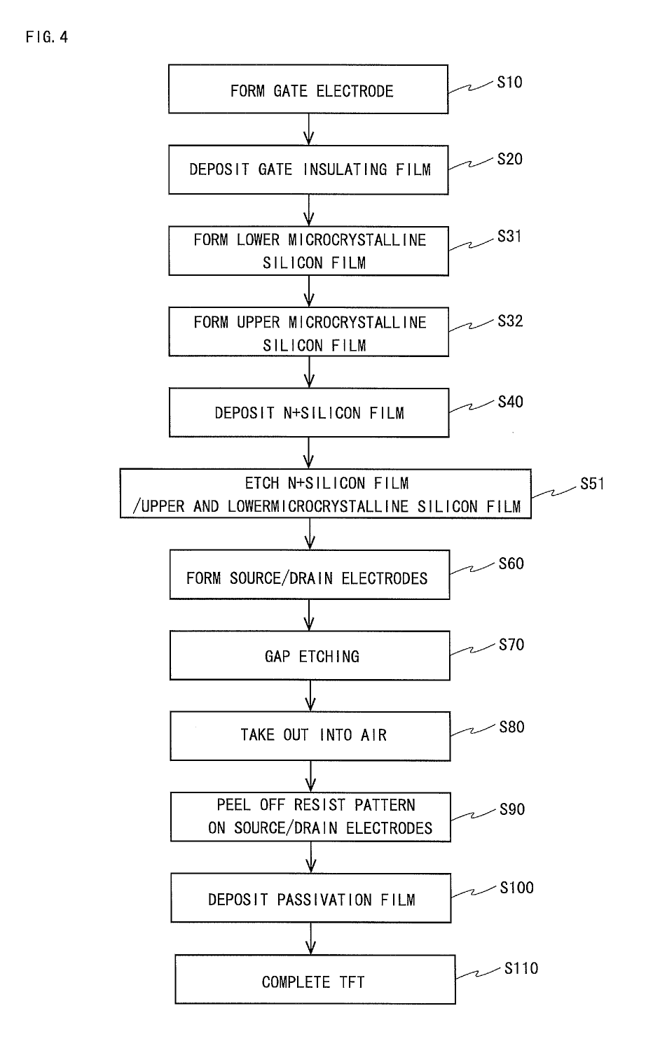

FIG. 3 is a cross-sectional view showing a cross section after formation of contact layers 50a and 50b of an inverted staggered type microcrystalline silicon TFT 13 which is a second comparative example. FIG. 4 is a step flowchart showing a method of fabricating the TFT 13 shown in FIG. 3. Of the components shown in FIG. 3 and the steps shown in FIG. 4, the same components as those shown in FIG. 1 and the same steps as those shown in FIG. 2 which are used to describe the first comparative example are denoted by the same reference characters and different components and different steps will be mainly described. Note that an after-treatment process to prevent after-corrosion caused by residual chlorine gas, and hydrogen plasma treatment to terminate the dangling bonds of silicon atoms on a surface of a microcrystalline silicon film are also performed. However, description thereof is omitted in the second comparative example, too.

As shown in FIGS. 3 and 4, a gate electrode 25 is formed on a glass substrate 20 which is an insulating substrate (step S10). Agate insulating film 30 made of a silicon nitride film is deposited so as to cover the entire surface of the glass substrate 20 including the gate electrode 25 (step S20).

A microcrystalline silicon film (hereinafter, referred to as the “lower microcrystalline silicon film”) of a film thickness of 50 nm, for example, is deposited on a surface of the gate insulating film 30, using a high density plasma enhanced CVD apparatus (step S31). The lower microcrystalline silicon film is deposited using monosilane gas and argon gas as raw material gas, and the grain size thereof is 2 to 100 nm. Then, using the same high density plasma enhanced CVD apparatus, a microcrystalline silicon film (hereinafter, referred to as the “upper microcrystalline silicon film”) of a film thickness of 30 nm, for example, is deposited on a top surface of the lower microcrystalline silicon film by changing the deposition conditions (step S32). The upper microcrystalline silicon film has a structure close to an amorphous silicon film where grains are not observed almost at all. At step S32, too, raw material gas containing monosilane gas and argon gas is used as raw material gas. However, at step S32, raw material gas where the flow rate of argon gas is reduced over the case of step S31 is used.

Furthermore, using the same high density plasma enhanced CVD apparatus, an N+ silicon film made of an amorphous silicon film is deposited on a surface of the microcrystalline silicon film by changing the deposition conditions (step S40). Then, the glass substrate 20 having the N+ silicon film formed thereon is taken out of the high density plasma enhanced CVD apparatus into the air. At this time, since the lower microcrystalline silicon film is covered with the N+ silicon film and the upper microcrystalline silicon film, oxygen in the air is adsorbed on a surface of the N+ silicon film. However, the adsorbed oxygen hardly diffuses in the lower microcrystalline silicon film through the N+ silicon film and the upper microcrystalline silicon film.

Using, as a mask, a resist pattern formed on the surface of the N+ silicon film, the N+ silicon film, the upper microcrystalline silicon film, and the lower microcrystalline silicon film are consecutively etched in this order by a dry etching method (step S51). By this, an island-like active layer 47 of a two-layer structure is formed that extends laterally over the gate electrode 25 as viewed from the top and that has a microcrystalline silicon film 48 and a microcrystalline silicon film 49 stacked on a top surface of the microcrystalline silicon film 48. On a top surface of the active layer 47 is formed the N+ silicon film of the same shape as the active layer 47.

A titanium film is deposited so as to cover the entire surface of the glass substrate 20 including the N+ silicon film. Using, as a mask, a resist pattern 70 formed on a surface of the titanium film, the titanium film is etched using a dry etching apparatus, thereby forming a source electrode 60a and a drain electrode 60b (step S60).

Furthermore, using the same dry etching apparatus and using the resist pattern 70 as a mask, the N+ silicon film is etched (gap etching) (step S70). As shown in FIG. 3, by the gap etching, the N+ silicon film is separated from each other to the left and right, whereby two contact layers 50a and 50b are formed and a surface of the microcrystalline silicon film 49 composing the active layer 47 is exposed. However, since the microcrystalline silicon film 48 is covered with the microcrystalline silicon film 49, a surface of the microcrystalline silicon film 48 is not exposed.

To peel off the resist pattern 70, the glass substrate 20 having been subjected to the gap etching is taken out of the dry etching apparatus into the air (step S80). At this time, oxygen in the air is adsorbed on the surface of the microcrystalline silicon film 49. However, since the microcrystalline silicon film 49 has a structure close to an amorphous silicon film, the adsorbed oxygen hardly diffuses in the microcrystalline silicon film 48 through the microcrystalline silicon film 49.

The resist pattern 70 formed on the source electrode 60a and the drain electrode 60b is peeled off (step S90). Then, a passivation film is deposited so as to cover the entire surface of the glass substrate 20 including the source electrode 60a and the drain electrode 60b, thereby sealing a TFT 13 (step S100). The passivation film is a silicon nitride film of a film thickness of 265 nm, for example. Furthermore, a heating process is performed in a nitrogen atmosphere for one hour, whereby the TFT 13 is completed (step S110).

### 1.2.1 Problems in the Second Comparative Example

According to the second comparative example, the active layer 47 of the TFT 13 is composed of stacked two microcrystalline silicon films 48 and 49. When the glass substrate 20 where the surface of the microcrystalline silicon film 49 is exposed by gap etching is taken out of the dry etching apparatus into the air, oxygen in the air is adsorbed on the surface of the microcrystalline silicon film 49. However, the microcrystalline silicon film 49 has a structure close to an amorphous silicon film and does not have columnar crystal structures almost at all. Due to this, the oxygen adsorbed on the surface of the microcrystalline silicon film 49 cannot diffuse in the microcrystalline silicon film 48 having columnar crystal structures, through the microcrystalline silicon film 49. Therefore, the TFT 13 satisfies the first condition.

However, as is also clear from FIG. 3, the microcrystalline silicon film 49 having a structure close to an amorphous silicon film is formed between the microcrystalline silicon film 48 composing the active layer 47, and the N+ silicon films composing the contact layers 50a and 50b. Therefore, an on-current flows from the drain electrode 60b, through the contact layer 50b, the microcrystalline silicon film 49 of the active layer 47, the microcrystalline silicon film 48, the microcrystalline silicon film 49, and the contact layer 50a, to the source electrode 60a. Since the on-current passes through the microcrystalline silicon film 49 twice along the way from the drain electrode 60b to the source electrode 60a, the mobility of the TFT 13 decreases. In this case, in the TFT 13, the contact layers 50a and 50b are indirect contact with the microcrystalline silicon film 49 having a structure close to an amorphous silicon film, which is one of the two microcrystalline silicon films 48 and 49 composing the active layer 47, and are not in direct contact with the microcrystalline silicon film 48 having columnar crystal structures. As such, since the N+ silicon films are not in direct contact with the microcrystalline silicon film 48 having columnar crystal structures, the TFT 13 does not satisfy the first condition. Therefore, the mobility of the TFT 13 decreases.

As is clear from the above description, the TFT 12 of the first comparative example satisfies the second condition, but does not satisfy the first condition. On the other hand, the TFT 13 of the second comparative example satisfies the first condition, but does not satisfy the second condition. Hence, in both of the TFTs 12 and 13, the mobility decreases.

In view of this, a configuration of a microcrystalline silicon TFT that satisfies both of the first and second conditions and has a high mobility, and a fabrication method therefor will be described next.

### 2. Embodiment

### 2.1 Configuration of a TFT

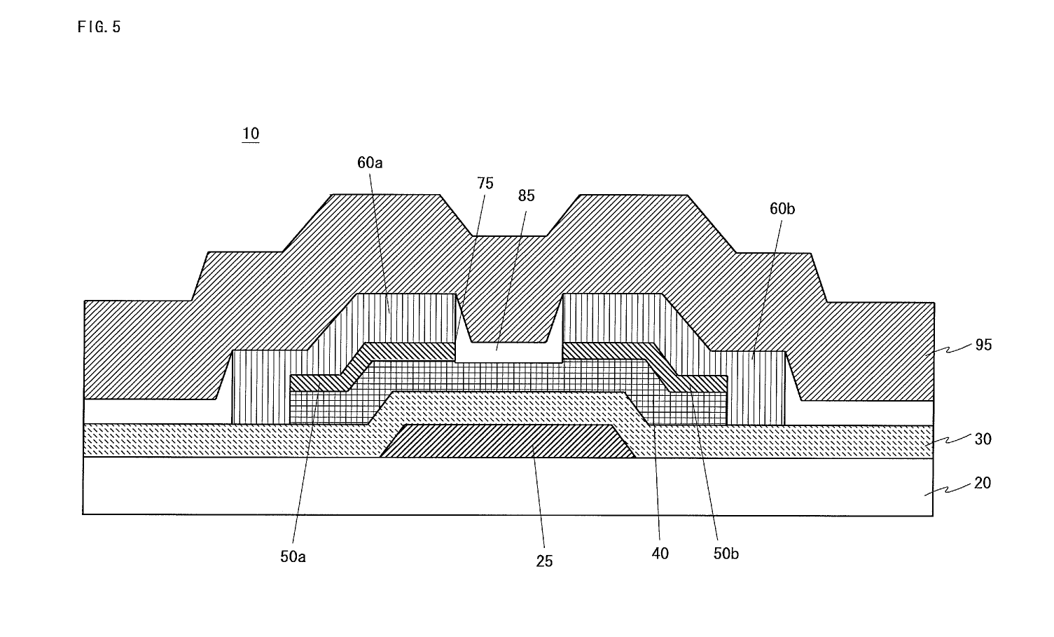

FIG. 5 is a cross-sectional view showing a configuration of an inverted staggered type microcrystalline silicon TFT 10 according to the present embodiment. With reference to FIG. 5, a configuration of the microcrystalline silicon TFT 10 will be described. Note that the same components as those shown in FIGS. 1 and 3 will be described, denoted by the same reference characters.

As shown in FIG. 5, a gate electrode 25 made of a metal film such as a titanium film is formed on a glass substrate 20 which is an insulating substrate. A gate insulating film 30 is formed so as to cover the entire surface of the glass substrate 20 including the gate electrode 25.

An island-like active layer 40 extending laterally over the gate electrode 25 as viewed from the top and made of a microcrystalline silicon film is formed on a surface of the gate insulating film 30. At left and right surface edges of the active layer 40 are respectively formed two contact layers 50a and 50b made of N+ silicon films and separated from each other to the left and right.

There are formed a source electrode 60a extending from a right edge of the contract layer 50a onto a portion of the gate insulating film 30 on the left side so as to cover the contact layer 50a, and a drain electrode 60b extending from a left edge of the contract layer 50b onto a portion of the gate insulating film 30 on the right side so as to cover the contact layer 50b. By this, the source electrode 60a is electrically connected to the active layer 40 through the contact layer 50a, and the drain electrode 60b is electrically connected to the active layer 40 through the contact layer 50b. The source electrode 60a and the drain electrode 60b are made of metal films such as titanium films. Note that an etching stopper layer is not provided on a top surface of the active layer 40.

A recess 75 which is sandwiched between the source electrode 60a and the drain electrode 60b and between the contact layer 50a and the contact layer 50b is formed on the surface of the active layer 40. An insulating layer 85 is formed so as to completely cover a surface of the recess 75. The insulating layer 85 is also formed on a portion of the gate insulating film 30 on the further left side from a left edge of the source electrode 60a, and on a portion of the gate insulating film 30 on the further right side from a right edge of the drain electrode 60b. However, the insulating layer 85 is not formed on surfaces of the source electrode 60a and the drain electrode 60b. A passivation film 95 made of, for example, a silicon nitride film is formed so as to cover the entire surface of the glass substrate 20 including the TFT 10. Therefore, the surface of the active layer 40 in the recess 75 is covered not only with the insulating layer 85, but also further with the passivation film 95.

As is clear from the above description, the TFT 10 has, as the active layer 40, a single microcrystalline silicon film having columnar crystal structures and has, as the contact layers 50a and 50b, N+ silicon films. The contact layers 50a and 50b are formed so as to come into direct contact with the active layer 40.

### 2.2 Method of Fabricating a TFT

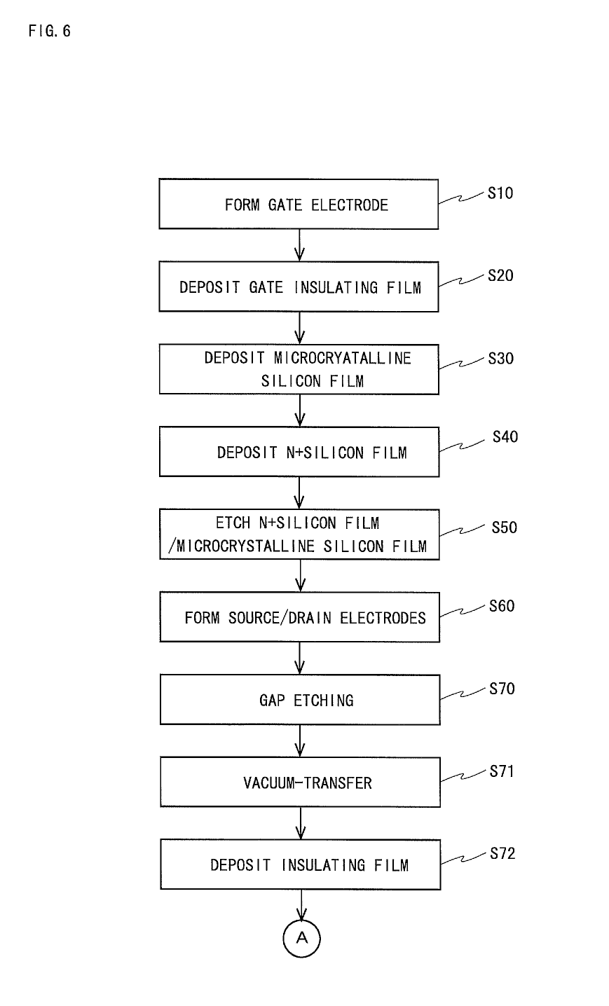

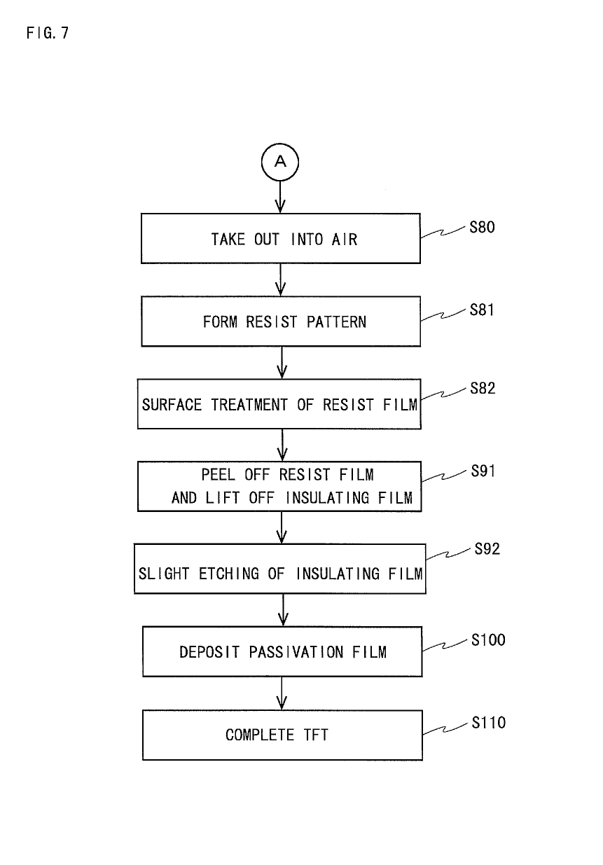

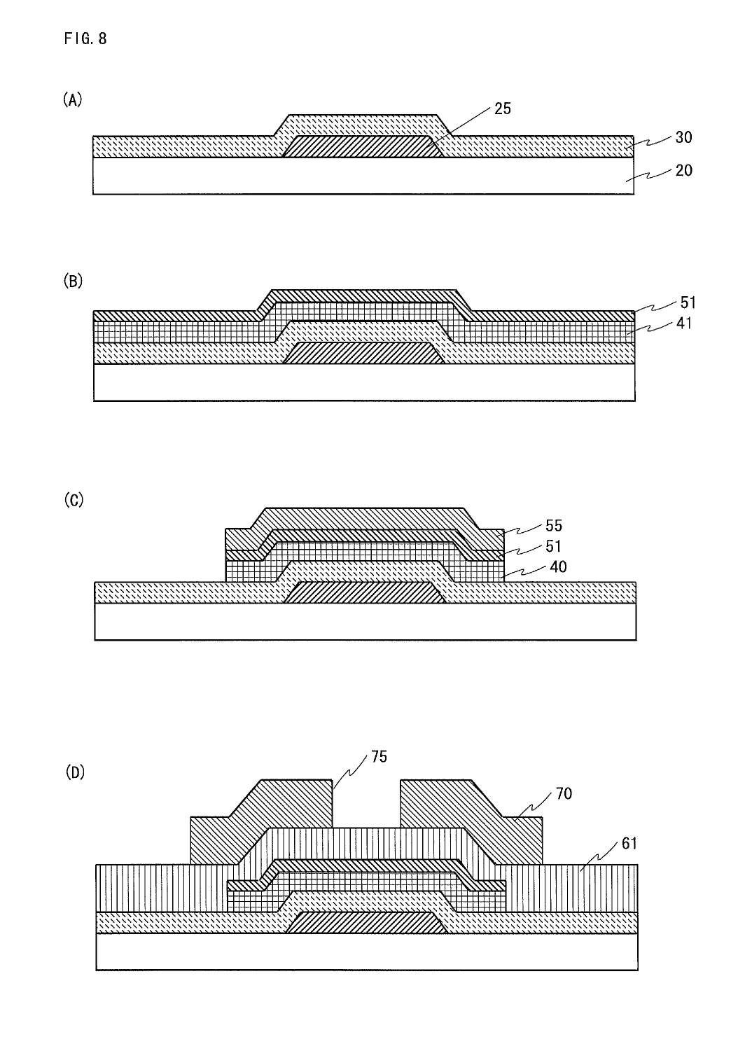

FIGS. 6 and 7 are step flowcharts showing the fabrication steps of the TFT 10 shown in FIG. 5, and FIGS. 8 to 11 are step cross-sectional views showing each fabrication step of the TFT 10 shown in FIG. 5. Note that in the following description, of the steps shown in FIGS. 6 and 7 and the components shown in FIGS. 8 to 11, the same components as those shown in FIGS. 1 and 3 and the same steps as those shown in FIGS. 2 and 4 which are used to describe the first and second comparative examples will be described, denoted by the same reference characters.

As shown in FIG. 8(A), a titanium film (not shown) of a film thickness of 100 nm, for example, is deposited on a glass substrate 20 which is an insulating substrate. The titanium film is patterned using a photolithography technique to form agate electrode 25 (step S10). Note that instead of a titanium film, a metal film such as a molybdenum (Mo) film or a tungsten (W) film, or a metal film made of an alloy thereof may be deposited. Then, a gate insulating film 30 made of a silicon nitride film of a film thickness of 410 nm, for example, is deposited by a plasma enhanced CVD (Chemical Vapor Deposition) method, etc., so as to cover the entire surface of the glass substrate 20 including the gate electrode 25 (step S20). Note that as the gate insulating film 30, a silicon oxide (SiO2) film may be used instead of a silicon nitride film.

As shown in FIG. 8(B), a microcrystalline silicon film 41 of a film thickness of 50 nm, for example, is deposited on a surface of the gate insulating film 30, using a high density plasma enhanced CVD apparatus (step S30). The deposition conditions of the microcrystalline silicon film 41 are, for example, as follows. The microwave frequency is 915 MHz, the RF power is 3.2 W/cm², the pressure in the chamber is 20 mTorr, the flow rate of monosilane gas is 13 sccm, the flow rate of argon gas is 255 sccm, the spacing between an anode electrode and a cathode electrode is 150 mm, and the substrate setting temperature is 250° C. By this, the microcrystalline silicon film 41 including grains of a grain size of 2 to 100 nm and having columnar crystal structures is deposited.

Furthermore, using the same high density plasma enhanced CVD apparatus, an N+ silicon film 51 is deposited on a surface of the microcrystalline silicon film 41 (step S40). The N+ silicon film 51 is an amorphous silicon film containing N-type impurities and the film thickness thereof is, for example, 50 nm.

As shown in FIG. 8(C), a resist pattern 55 is formed on a surface of the N+ silicon film 51, using a photolithography technique. Using the resist pattern 55 as a mask, the N+ silicon film 51 and the microcrystalline silicon film 41 are etched in this order using a dry etching apparatus (step S50). By this, an active layer 40 which is obtained by patterning the microcrystalline silicon film 41 into an island, and the N+ silicon film 51 having the same shape as the active layer 40 and stacked on a top surface of the active layer 40 are formed.

As shown in FIG. 8(D), a titanium film 61 of a film thickness of 100 nm is deposited using a sputtering method, etc., so as to cover the entire surface of the glass substrate 20 including the N+ silicon film 51. Next, a resist pattern 70 is formed on a surface of the titanium film 61, using a photolithography technique.

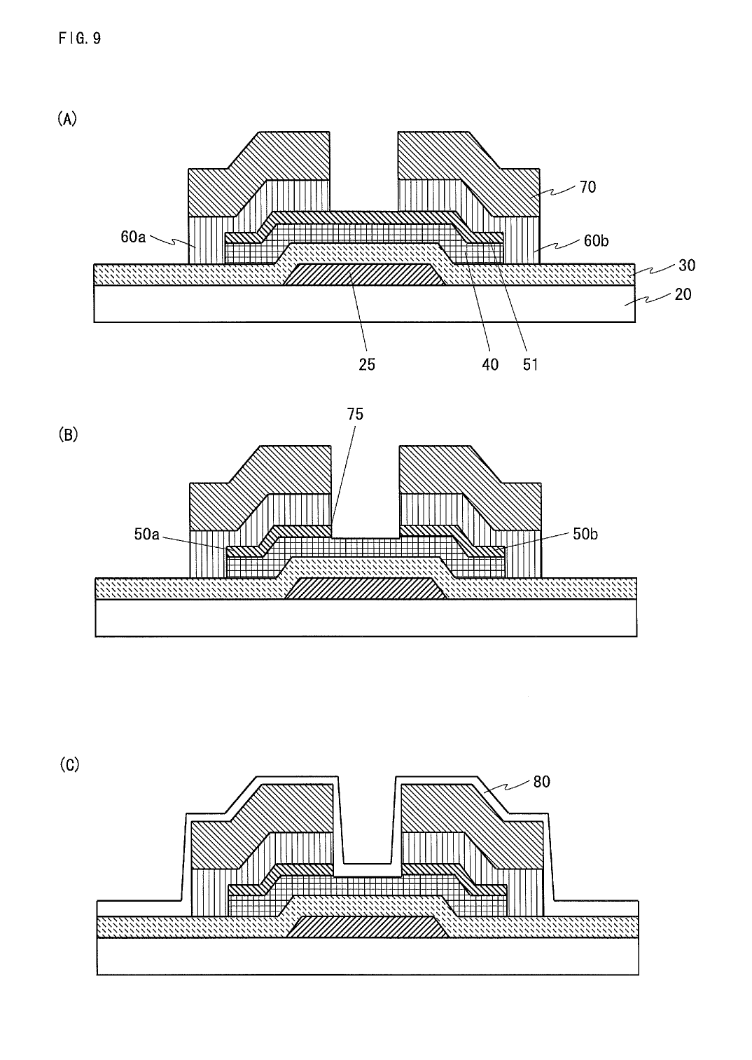

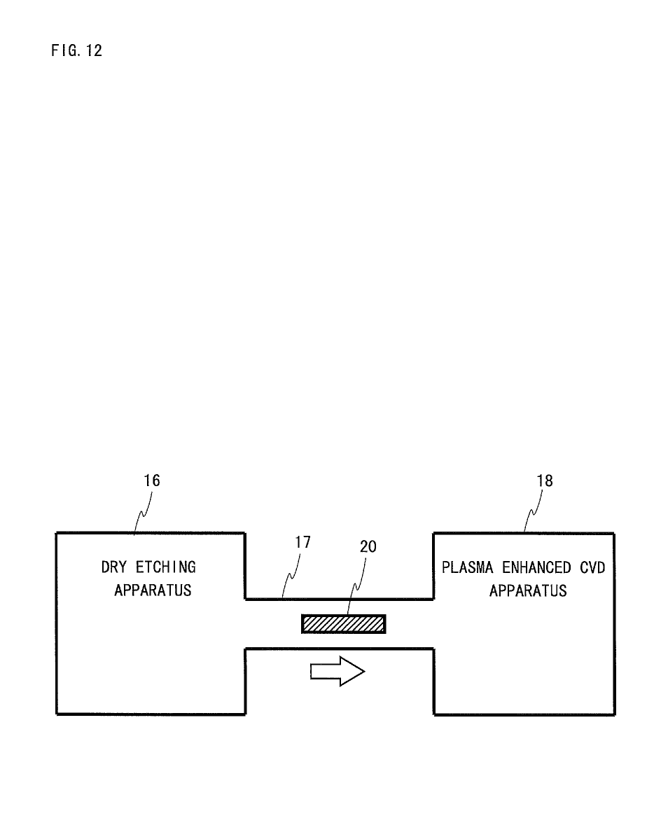

As shown in FIG. 9(A), using the resist pattern 70 as a mask, the titanium film 61 is etched using a dry etching apparatus 16 shown in FIG. 12 (step S60). By this, a source electrode 60a extending from an upper left surface of the N+ silicon film 51 onto a portion of the gate insulating film 30 on the left side, and a drain electrode 60b extending from an upper right surface of the N+ silicon film 51 onto a portion of the gate insulating film 30 on the right side are formed. Note that as the source electrode 60a and the drain electrode 60b, as in the case of the gate electrode 25, instead of the titanium film 61, any other metal film such as a molybdenum film or a tungsten film, or an alloy film thereof may be deposited.

As shown in FIG. 9(B), with the resist pattern 70 remaining on the source electrode 60a and the drain electrode 60b, the N+ silicon film 51 is etched (gap etching) using the dry etching apparatus 16 (step S70). By this, the N+ silicon film 51 is separated from each other to the left and right, whereby two contact layers 50a and 50b are formed on left and right surface edges of the active layer 40, respectively. A recess 75 is formed on a portion of a surface of the active layer 40 sandwiched between the two contact layers 50a and 50b. The recess 75 is sandwiched between the source electrode 60a and the drain electrode 60b and between the contact layer 50a and the contact layer 50b. At a bottom surface of the recess 75, the surface of the microcrystalline silicon film composing the active layer 40 is exposed.

Furthermore, in order to prevent the reliability of the TFT 10 from decreasing due to after-corrosion which is caused by chlorine gas contained in etching gas for the titanium film 61 remaining in the TFT 10, an after-treatment process by carbon tetrafluoride (CF4) gas plasma is performed using the dry etching apparatus 16.

With the resist pattern 70 remaining on the source electrode 60a and the drain electrode 60b, the glass substrate 20 having the contact layers 50a and 50b formed thereon is vacuum-transferred from the dry etching apparatus 16 to a plasma enhanced CVD apparatus 18 connected thereto by a vacuum path 17 (step S71). Since the degree of vacuum of the vacuum path 17 is maintained at 5.0×E−5 Torr or more, there is almost no oxygen in the vacuum path 17. Hence, oxygen is hardly adsorbed on the exposed surface of the active layer 40 while the glass substrate 20 is transferred. Therefore, oxygen hardly diffuses in the active layer 40 along grain boundaries.

As shown in FIG. 9(C), in the plasma enhanced CVD apparatus 18, an insulating film 80 is deposited so as to cover the entire surface of the glass substrate 20 including the resist pattern 70 (step S72). The insulating film 80 is a silicon nitride film of a film thickness of 80 nm, for example. By this, not only the surface of the active layer 40 which is exposed at the bottom surface of the recess 75, but also a surface of the resist pattern 70 is covered by the insulating film 80.

The glass substrate 20 having the insulating film 80 deposited thereon is taken out of the plasma enhanced CVD apparatus 18 into the air (step S80). At this time, since the surface of the active layer 40 is covered with the insulating film 80, even if the glass substrate 20 is taken out of the plasma enhanced CVD apparatus 18 into the air, oxygen in the air is hardly adsorbed on the surface of the active layer 40 and further hardly diffuses in the active layer 40.

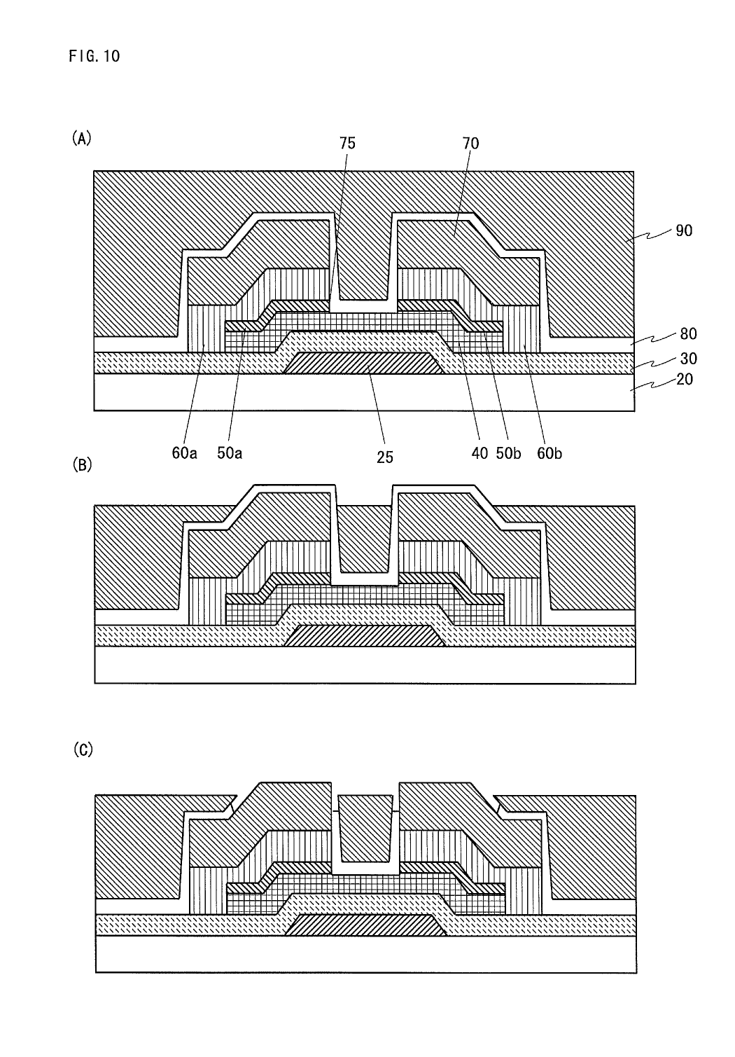

As shown in FIG. 10(A), a low-viscosity photoresist is applied to the entire surface of the glass substrate 20 having the resist pattern 70 covered with the insulating film 80. By this, the photoresist spreads such that a surface thereof is flattened, covering the glass substrate 20. Furthermore, the photoresist is cured by baking, whereby a resist film 90 is formed (step S81). The resist film 90 thus formed completely covers the insulating film 80.

Then, by a chemical mechanical polishing method, projections and depressions on a surface of the resist film 90 which occur upon curing of the photoresist are polished to flatten the resist film 90 and to adjust the film thickness of the resist film 90 in order to efficiently perform surface treatment of the resist film 90 which will be described later.

As shown in FIG. 10(B), to perform surface treatment of the resist film 90, the glass substrate 20 having the resist film 90 formed thereon is immersed in a resist development solution (step S82). By this, the resist film 90 is dissolved little by little in the resist development solution from the surface thereof, and a surface of a portion of the insulating film 80 at a location where the film thickness of the resist film 90 is smallest is exposed.

As shown in FIG. 10(C), the glass substrate 20 is pulled out of the resist development solution and is immersed in an etchant such as hot phosphoric acid (H3PO4). Since the insulating film 80 is a silicon nitride film, by immersing the glass substrate 20 in the hot phosphoric acid, a portion of the insulating film 80 that is not covered with the resist film 90 is removed.

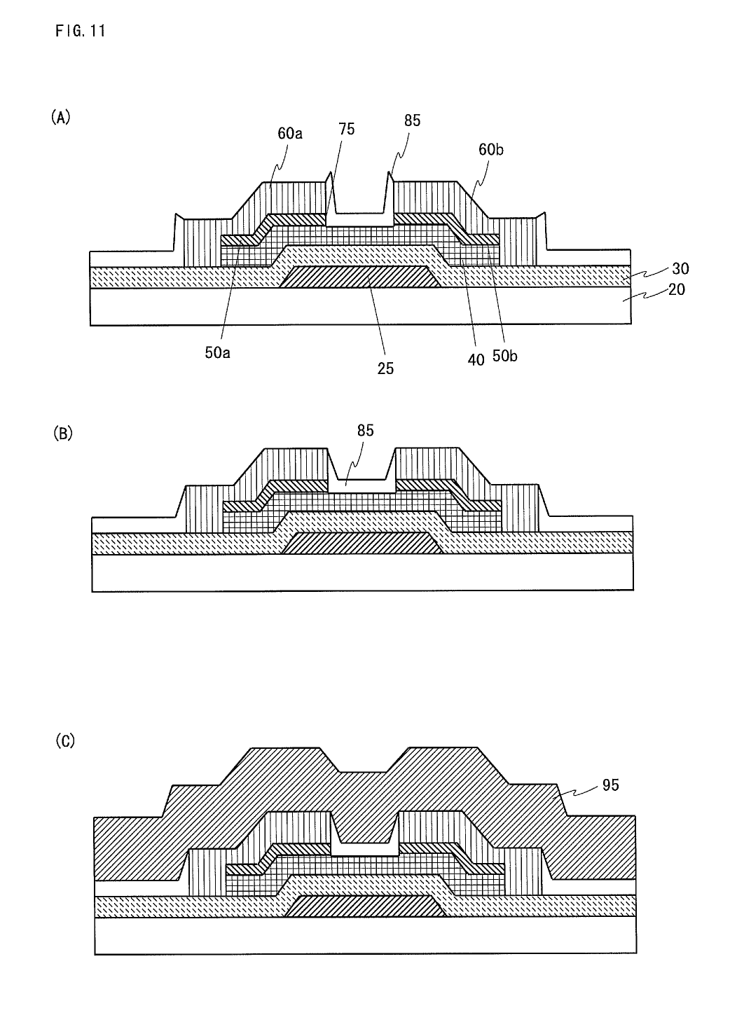

As shown in FIG. 11(A), the glass substrate 20 where the portion of the insulating film 80 that is not covered with the resist film 90 is removed is immersed again in a resist development solution (step S91). By this, not only the resist film 90 but also the resist pattern 70 starts to be dissolved in the resist development solution. Then, not only portions of the resist film 90 on the gate insulating film 30 and in the recess 75 are dissolved in the resist development solution and removed, but also portions of the resist pattern 70 on the source electrode 60a and the drain electrode 60b are further dissolved in the resist development solution and removed. In addition, when the resist pattern 70 is removed, the insulating film 80 covering the resist pattern 70 is also lifted off and thus is removed simultaneously. As a result, an insulating layer 85 remains only on the surface of the recess 75 and on portions of the gate insulating film 30 around the source/drain electrodes 60a and 60b.

As shown in FIG. 11(B), slight etching is performed to remove a portion of the insulating film 80 that has not been able to be removed by the lift-off and to adjust the shape of the insulating layer 85 (step S92). The slight etching is performed by immersion in an etchant such as hot phosphoric acid.

Hydrogen plasma treatment is performed using the plasma enhanced CVD apparatus. The hydrogen plasma treatment is performed to terminate the dangling bonds of silicon atoms formed on the surface of the active layer 40. As shown in FIG. 11(C), using the same plasma enhanced CVD apparatus, a passivation film 95 is deposited so as to cover the entire surface of the glass substrate 20, thereby sealing a TFT 10 (step S100). The passivation film 95 is a silicon nitride film of a film thickness of 265 nm, for example. Then, the glass substrate 20 is heated in a nitrogen atmosphere at 200° C. for one hour, whereby the TFT 10 is completed (step S110).

### 2.3 Measurement Results

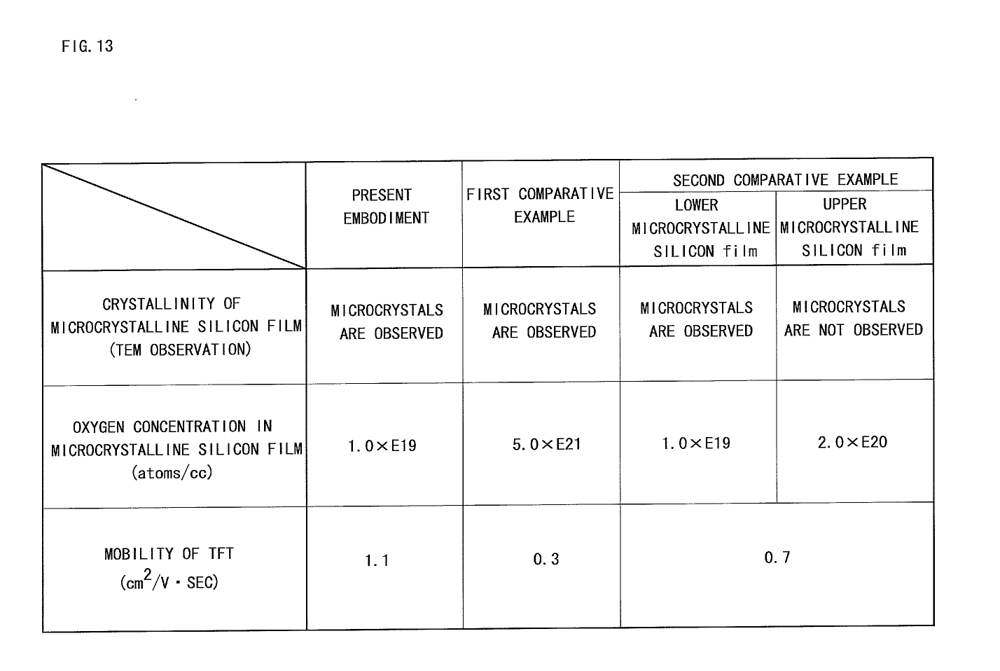

FIG. 13 is a diagram showing the crystallinity observation results of the active layers 40, 46, and 47 and measurement results of mobility of the TFTs 10, 12, and 13 of the present embodiment, the first comparative example, and the second comparative example. Observation is performed using a TEM (Transmission Electron Microscope) and the crystallinity of the active layers 40, 46, and 47 is evaluated by determining whether microcrystals are formed in microcrystalline silicon films composing the active layers 40, 46, and 47.

As shown in FIG. 13, the active layer 46 of the TFT 12 of the first comparative example is made of a single microcrystalline silicon film and it is observed that microcrystals of a grain size of 2 to 100 nm are formed in the microcrystalline silicon film. The active layer 47 of the TFT 13 of the second comparative example is composed of a silicon film of a two-layer structure having the upper microcrystalline silicon film 49 stacked on the surface of the lower microcrystalline silicon film 48. It is observed that microcrystals of a grain size of 2 to 100 nm are formed in the microcrystalline silicon film 48. However, microcrystals are not observed in the microcrystalline silicon film 49. On the other hand, the active layer 40 of the TFT 10 according to the present embodiment is made of a single microcrystalline silicon film and it is observed that microcrystals of a grain size of 2 to 100 nm are formed.

Then, the concentrations of oxygen contained in the microcrystalline silicon films composing the active layers 40, 46, and 47 are measured by a SIMS (Secondary Ion microprobe Mass Spectrometer). As shown in FIG. 13, it is found that the oxygen concentration in the active layer 46 of the first comparative example is as high as 5.0×E21. This is considered to be because oxygen that is adsorbed on the surface of the active layer 46 when taking it out from the dry etching apparatus into the air after gap etching with the surface of the microcrystalline silicon film composing the active layer 46 being exposed diffuses in the active layer 46 along columnar crystal structures.

It is found that in the active layer 47 of the second comparative example, the oxygen concentration in the lower microcrystalline silicon film 48 is as low as 1.0×E19, and the oxygen concentration in the upper microcrystalline silicon film 49 is 2.0×E20 which is much higher than that in the microcrystalline silicon film 48. This is considered to be due to the following reason. Since the microcrystalline silicon film 48 is taken out into the air with the microcrystalline silicon film 48 being covered with the microcrystalline silicon film 49, oxygen in the air is adsorbed on the surface of the microcrystalline silicon film 49. However, the microcrystalline silicon film 49 has a structure close to an amorphous silicon film and does not have columnar crystal structures almost at all. As a result, the oxygen adsorbed on the surface of the microcrystalline silicon film 49 cannot diffuse in the microcrystalline silicon film 48 through the microcrystalline silicon film 49.

On the other hand, it is found that the oxygen concentration in the microcrystalline silicon film composing the active layer 40 according to the present embodiment is as low as 1.0×E19. This is considered to be because the active layer 40 is taken out of the plasma enhanced CVD apparatus 18 into the air after gap etching with the surface of the active layer 40 being covered with the insulating film 80, oxygen in the air is not adsorbed on the surface of the active layer 40.

In the TFTs 10, 12, and 13 of the present embodiment, the first comparative example, and the second comparative example, the L/W of their active layers is 12 μm/20 μm. The mobility of each of the TFTs 10, 12, and 13 in a saturation region is measured with a voltage Vds applied between the source and drain electrodes 60a and 60b being set to 10 V.

As shown in FIG. 13, while the mobility of the TFT 12 of the first comparative example is 0.3 cm²/V·sec and the mobility of the TFT 13 of the second comparative example is 0.7 cm²/V·sec, the mobility of the TFT 10 according to the present embodiment is 1.1 cm²/V·sec which is the highest of all. From these results, it is considered that in the TFT 12 of the first comparative example the mobility decreases due to the influence of oxygen diffusing in the active layer 46.

In the TFT 13 of the second comparative example, since oxygen does not diffuse in the microcrystalline silicon film 48 composing the active layer 47, the oxygen concentration in the microcrystalline silicon film 48 decreases. It is considered that due to this, the mobility of the TFT 13 is higher than that of the TFT 12 of the first comparative example. However, the microcrystalline silicon film 48 is not in direct contact with the contact layers 50a and 50b but is in contact with the contact layers 50a and 50b through the microcrystalline silicon film 49. By this, the contact resistance between the microcrystalline silicon film 48 and the contact layer 50a and between the microcrystalline silicon film 48 and the contact layer 50b increases. It is considered that as a result the mobility of the TFT 13 is lower than that of the TFT 10 according to the present embodiment which will be described later.

On the other hand, in the TFT 10 according to the present embodiment, not only the oxygen concentration in the active layer 40 is low, but also the active layer 40 is in direct contact with the contact layers 50a and 50b. It is considered that by this the mobility of the TFT 10 is lower than those of the cases of the TFTs 12 and 13 of the first and second comparative examples.

Note that according to the document (J. Appl. Phys., Vol. 96, No. 4, 2004), when the oxygen concentration in a microcrystalline silicon film is lower than 2×E19/cm³, the mobility is as high as about 1.0 cm²/V·sec. In addition, as the oxygen concentration becomes higher than 2×E19/cm³, the mobility decreases. The document describes that from these facts, to increase the mobility of the microcrystalline silicon film, the oxygen concentration in the microcrystalline silicon film needs to be lower than 2×E19/cm³. This result also matches the results shown in FIG. 13.

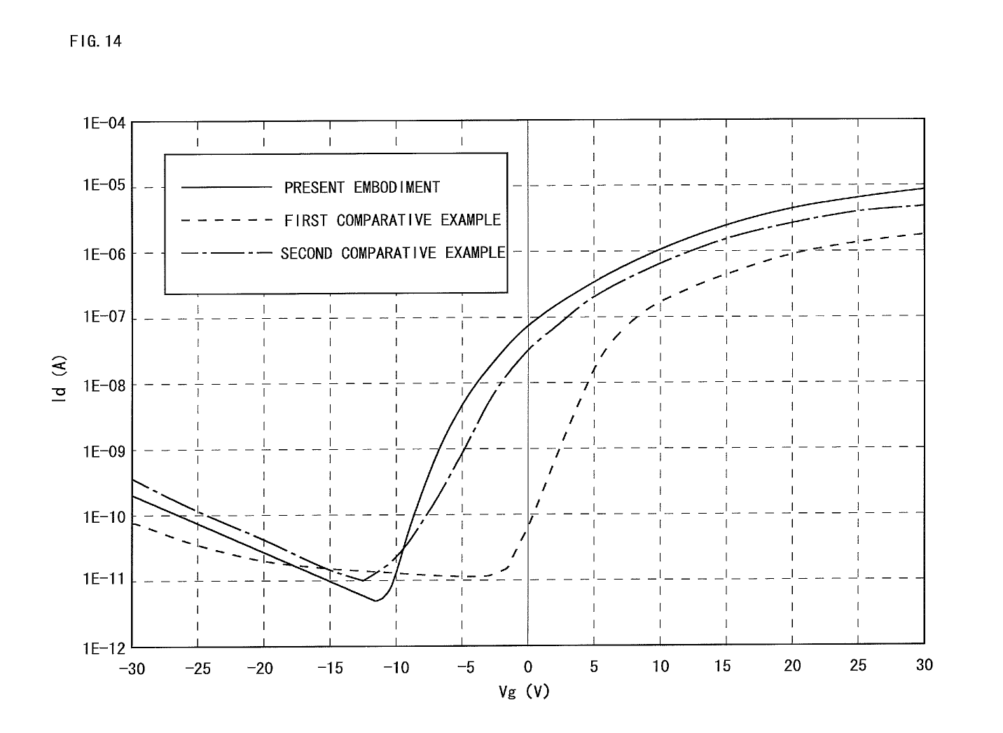

FIG. 14 is a diagram showing the measurement results of the gate voltage-drain current (Vg-Id) characteristics of the TFTs 10, 12, and 13 of the present embodiment, the first comparative example, and the second comparative example. The gate voltage-drain current characteristics are also measured in a saturation region, with a voltage Vds applied between the source and drain electrodes 60a and 60b being set to 10 V. As shown in FIG. 14, the on-current is the highest in the case of the TFT 10 according to the present embodiment, and decreases in the order of the TFT 13 of the second comparative example and the TFT 12 of the first comparative example.

In addition, while the minimum value of the off-current is 1.05×E−11 A for the TFT 12 of the first comparative example and is 1.02×E−11 A for the TFT 13 of the second comparative example, the minimum value of the off-current of the TFT 10 according to the present embodiment is 4.94×E−12 A which is the lowest of all.

The reason that the on-current of the TFT 10 according to the present embodiment is thus high is considered to be that the TFT 10 satisfies the first and second conditions, whereby the mobility thereof becomes the highest. In addition, the off-current being low is considered to be due to the following reason. A surface on the back-channel side of the active layer 40 of the TFT 10 is not exposed to the air before depositing the insulating film 80, and is not subjected to any surface treatment other than an after-treatment process. Hence, the surface on the back-channel side of the active layer 40 is clean. In addition, in the recess 75, not only the insulating layer 85 obtained by patterning the insulating film 80, but also the passivation film 95 is further stacked, and thus, the surface on the back-channel side is less likely to be contaminated. It is considered that since the surface on the back-channel side of the active layer 40 is thus kept in a clean state, crystal defects which are the cause of the occurrence of off-current are less likely to be formed.

### 2.4 Effects

According to the present embodiment, a glass substrate 20 where a surface of a microcrystalline silicon film composing an active layer 40 is exposed by gap etching is vacuum-transferred from a dry etching apparatus 16 to a plasma enhanced CVD apparatus 18 through a vacuum path 17. Then, after depositing an insulating film 80 by the plasma enhanced CVD apparatus 18 so as to completely cover the exposed surface of the active layer 40, the glass substrate 20 is taken out into the air. In this case, since the surface of the active layer 40 is not exposed to oxygen in the air, oxygen in the air is not adsorbed on the surface of the active layer 40. By this, the oxygen concentration in the active layer 40 does not increase and thus a TFT 10 satisfies the first condition.

In addition, as described above, since N+ silicon films composing contact layers 50a and 50b are in direct contact with the microcrystalline silicon film composing the active layer 40, the contact resistance between the contact layer 50a and the active layer 40 and between the contact layer 50b and the active layer 40 decreases. By this, the TFT 10 satisfies the second condition. As such, since the TFT 10 according to the present embodiment satisfies both of the first and second conditions, the mobility of the TFT 10 can be increased and the on-current can also be increased.

In addition, according to the present embodiment, in a recess 75 formed on the surface of the active layer 40 by gap etching, not only an insulating layer 85 but also a passivation film 95 is further stacked. As a result, the surface on the back-channel side of the active layer 40 is protected by the thick insulating film. This makes impurities less likely to enter the surface on the back-channel side of the active layer 40 from the outside, and thus, crystal defects resulting from impurities are less likely to be formed. Hence, the off-current of the TFT 10 decreases.

In addition, according to the present embodiment, there is no need to form an etching stopper layer for protecting the active layer 40 from being etched upon gap etching. By this, the TFT 10 can be fabricated using photomasks of the same number as that of the conventional fabrication method.

### 2.5 Variant

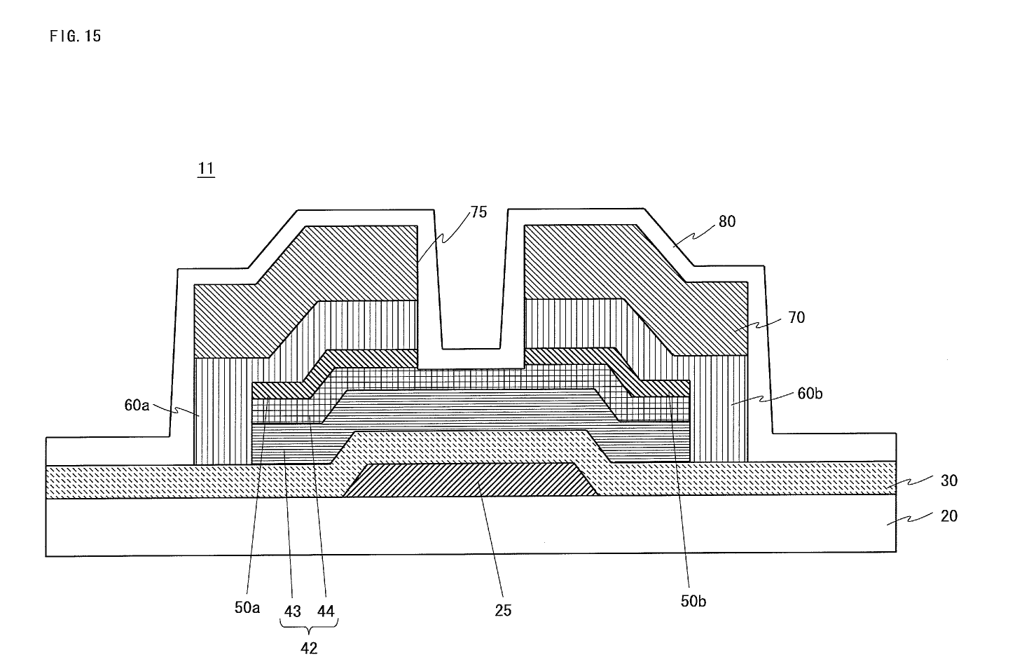

FIG. 15 is a cross-sectional view corresponding to FIG. 9(C) of an inverted staggered type microcrystalline silicon TFT 11 according to a variant of the present embodiment. Note that in the following description, of the components shown in FIG. 15, the same components as those shown in FIG. 9(C) are denoted by the same reference characters, and different components will be mainly described.

As shown in FIG. 15, an active layer 42 of a two-layer structure including a polycrystalline silicon film 43 and a microcrystalline silicon film 44 formed on a top surface of the polycrystalline silicon film 43 is formed on a top surface of a gate insulating film 30. As in the case of a TFT 10, since two contact layers 50a and 50b are formed at left and right surface edges of the microcrystalline silicon film 44, respectively, and are in direct contact with the microcrystalline silicon film 44, and the contact resistance between the microcrystalline silicon film 44 and the contact layer 50a and between the microcrystalline silicon film 44 and the contact layer 50b is low. Therefore, the TFT 11 satisfies the second condition.

In addition, as in the case of the TFT 10, a glass substrate 20 having the contact layers 50a and 50b formed thereon by gap etching is vacuum-transferred from a dry etching apparatus 16 to a plasma enhanced CVD apparatus 18, using a vacuum path 17. Then, after depositing an insulating film 80 on a surface of the microcrystalline silicon film 44 using the plasma enhanced CVD apparatus 18, the glass substrate 20 is taken out into the air. By depositing the insulating film 80, oxygen in the air is less likely to be adsorbed on the surface of the microcrystalline silicon film 44, and thus, oxygen in the air is less likely to diffuse in the microcrystalline silicon film 44. As such, the TFT 11 also satisfies the first condition. Note that the polycrystalline silicon film 43 is formed by, for example, laser-annealing an amorphous silicon film deposited on the gate insulating film 30. Note also that as in the case of the TFT 10, the microcrystalline silicon film 44 is deposited using a high density plasma enhanced CVD apparatus.

Therefore, the TFT 11 provides the same effects as those provided by the TFT 10. Furthermore, the active layer 42 of the TFT 11 has the polycrystalline silicon film 43 with a high mobility on the side of a gate electrode 25. Hence, a higher on-current flows through the TFT 11 over the case of the TFT 10.

### 2.6 Other variants

In the present embodiment, a microcrystalline silicon film is described as an example of a microcrystalline semiconductor film composing an active layer 40. However, the present embodiment can also be applied in the same manner to an active layer made of a microcrystalline semiconductor film, e.g., a microcrystalline silicon-germanium film.

In the present embodiment, phosphorus ions which are N-type impurities are doped to form contact layers 50a and 50b. However, instead of phosphorus ions, boron (B) ions which are P-type impurities may be doped. In this case, a TFT is a P-channel type TFT.

### 3. Liquid Crystal Display Device

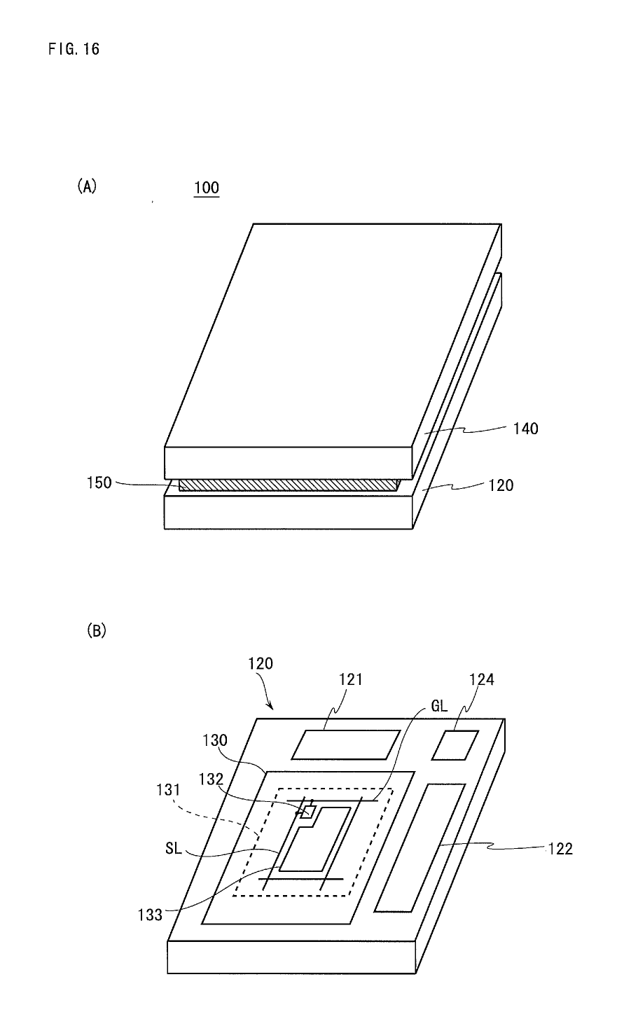

FIG. 16(A) is a perspective view showing a liquid crystal panel 100 of an active matrix-type liquid crystal display device, and FIG. 16(B) is a perspective view showing a TFT substrate 120 included in the liquid crystal panel 100 shown in FIG. 16(A). As shown in FIG. 16(A), the liquid crystal panel 100 is a fully monolithic-type panel including two glass substrates 120 and 140 disposed to face each other; and a sealing material 150 that seals a liquid crystal layer (not shown) sandwiched between the two glass substrates 120 and 140. Of the two glass substrates 120 and 140, a glass substrate having a plurality of pixel portions including TFTs, which are formed thereon in a matrix form, is referred to as the TFT substrate 120, and a glass substrate disposed to face the TFT substrate 120 and having a color filter, etc., formed thereon is referred to as the CF substrate 140.

As shown in FIG. 16(B), the TFT substrate 120 includes an image display portion 130 having a plurality of pixel portions 131 arranged therein. In each pixel portion 131 are formed a switching element 132 and a pixel electrode 133 connected to the switching element 132. Peripheral circuits such as a source driver 121 and a gate driver 122 are provided in a picture-frame portion around the image display portion 130. The gate driver 122 outputs to gate wiring lines GL control signals that control timing at which the switching elements 132 are turned on/off. The source driver 121 outputs to source wiring lines SL image signals that display images on the pixel portions 131, and control signals that control timing at which the image signals are outputted.

By activating the gate wiring lines GL in turn to place those switching elements 132 connected to the activated gate wiring line GL in an on state, image signals provided to the source wiring lines SL are provided to corresponding pixel electrodes 133 through the switching elements 132. The pixel electrodes 133 form pixel capacitances with a common electrode (not shown) formed on the CF substrate 140, and hold the provided image signals. Backlight light emitted from a backlight unit (not shown) provided on the underside of the TFT substrate 120 is transmitted through corresponding pixel portions 131 according to the image signals, whereby an image is displayed on the image display portion 130 of the liquid crystal panel 100.

In such a liquid crystal panel 100, by using microcrystalline silicon TFTs 10 as the switching elements 132 in the pixel portions 131, since the mobility of the microcrystalline silicon TFTs 10 is high, the size of the TFTs 10 can be reduced. By this, the aperture ratio of the liquid crystal panel 100 can be increased and the power consumption of the liquid crystal panel 100 can be reduced. In addition, since the TFTs 10 can perform switching operation at high speed, the TFTs 10 can charge image signals provided from the source wiring lines SL in the pixel capacitances in a short time. By this, high definition of the liquid crystal panel 100 can be achieved by increasing the number of pixel portions 131 or the frame rate can be increased.

In addition, peripheral circuits such as the gate driver 122 and the source driver 121 can be formed using TFTs 10 with a high mobility. By this, the circuit size of the peripheral circuits can be reduced and thus the size of the picture-frame portion of the liquid crystal panel 100 is reduced, enabling to miniaturize the liquid crystal panel 100.

Note that a liquid crystal display device is described as an example of a display device to which TFTs 10 are applicable. However, the TFTs 10 can also be applied to display devices such as organic EL (Electro Luminescence) display devices and plasma display devices.

### INDUSTRIAL APPLICABILITY

The present invention is suitable for display devices such as active matrix-type liquid crystal display devices, and is particularly suitable for switching elements formed in pixel portions of the display devices, or transistors composing drive circuits for driving the pixel portions.

### DESCRIPTION OF REFERENCE CHARACTERS

10 and 11: TFT (THIN FILM TRANSISTOR)
16: DRY ETCHING APPARATUS
17: VACUUM PATH
18: PLASMA ENHANCED CVD APPARATUS
20: GLASS SUBSTRATE (INSULATING SUBSTRATE)
25: GATE ELECTRODE
30: GATE INSULATING FILM
40 and 42: ACTIVE LAYER
41: MICROCRYSTALLINE SILICON FILM
50a and 50b: CONTACT LAYER
51: N+ SILICON FILM
60a: SOURCE ELECTRODE
60b: DRAIN ELECTRODE
70: RESIST PATTERN
75: RECESS
80: INSULATING FILM
85: INSULATING LAYER
90: RESIST FILM
95: PASSIVATION FILM (INSULATING FILM)

1. A thin film transistor formed on an insulating substrate, the thin film transistor comprising:
a gate electrode formed on the insulating substrate;
a gate insulating film that covers the gate electrode;
an active layer formed on a top surface of the gate insulating film so as to extend over the gate electrode as viewed from a top;
two contact layers formed on top surfaces of portions of the active layer at both edges, respectively; and
a source electrode and a drain electrode formed on top surfaces of the two contact layers, respectively, wherein
the active layer includes at least a microcrystalline semiconductor film on a back-channel side, and
a portion of a surface of the microcrystalline semiconductor film sandwiched between the two contact layers is covered with a first insulating film.

2. The thin film transistor according to claim 1, further comprising second insulating films formed on surfaces of the source electrode and the drain electrode, wherein
a film thickness of the first insulating film is thicker than a film thickness of the second insulating films.

3. The thin film transistor according to claim 1, wherein
the active layer further includes a polycrystalline semiconductor film, and
the microcrystalline semiconductor film is formed on a top surface of the polycrystalline semiconductor film.

4. The thin film transistor according to claim 1, wherein the two contact layers each are made of an impurity semiconductor film containing a high concentration of impurities.

5. A method of fabricating a thin film transistor formed on an insulating substrate, the method comprising the steps of:
forming a gate electrode on the insulating substrate;
forming a gate insulating film so as to cover the gate electrode;
forming a microcrystalline semiconductor film on a top surface of the gate insulating film;
forming an impurity semiconductor film containing a high concentration of impurities on a top surface of the microcrystalline semiconductor film;
forming a metal film on a top surface of the impurity semiconductor film;
forming a resist pattern on a top surface of the metal film;
forming a source electrode and a drain electrode by patterning the metal film using the resist pattern as a mask;
forming two contact layers and an active layer by patterning the impurity semiconductor film and the microcrystalline semiconductor film using the resist pattern as a mask, the two contact layers being separated from each other on the top surface of the microcrystalline semiconductor film; and
without causing a portion of a surface of the active layer sandwiched between the two contact layers to be exposed to oxygen, covering the portion of the surface of the active layer by a first insulating film.

6. The method of fabricating a thin film transistor according to claim 5, wherein
the step of covering the portion of the surface of the active layer by a first insulating film includes the steps of:
forming the first insulating film so as to cover at least a surface of the resist pattern and the portion of the surface of the active layer;
causing a part of the resist pattern to be exposed by removing at least a part of the first insulating film; and
allowing the first insulating film to remain on the portion of the surface of the active layer by lifting off the first insulating film on the resist pattern by removing the resist pattern by immersing the resist pattern in a first resist development solution.

7. The method of fabricating a thin film transistor according to claim 6, wherein the step of covering the portion of the surface of the active layer by a first insulating film further includes the step of wet etching the first insulating film remaining on the portion of the surface of the active layer.

8. The method of fabricating a thin film transistor according to claim 5, wherein
an etching apparatus used in the step of forming two contact layers is connected to a deposition apparatus used in the step of forming the first insulating film, by a vacuum path whose degree of vacuum is maintained at a predetermined value or less, and
the insulating substrate having the two contact layers formed thereon is transferred from the etching apparatus to the deposition apparatus through the vacuum path.

9. The method of fabricating a thin film transistor according to claim 6, wherein
the step of causing a part of the resist pattern to be exposed includes the steps of:
applying a photoresist onto the insulating substrate;
forming a resist film that completely covers the first insulating film, by curing the photoresist; and
causing at least a part of the first insulating film to be exposed by dissolving the resist film from a surface thereof, using a second resist development solution.

10. The method of fabricating a thin film transistor according to claim 9, wherein the step of forming a resist film further includes the step of flattening the surface of the resist film.

11. The method of fabricating a thin film transistor according to claim 5, further comprising the step of forming a second insulating film so as to cover the entire insulating substrate including the source electrode and the drain electrode.

12. A display device comprising: a thin film transistor according to claim 1; and an image display portion, wherein
the thin film transistor is used as a switching element in the image display portion.

13. A display device comprising: a thin film transistor according to claim 1; an image display portion, and a peripheral circuit that drives the image display portion, wherein
the image display portion includes the thin film transistor as a switching element, and the peripheral circuit includes the thin film transistor.
